(19) United States
(12) Patent Application Publication
(10) Pub. No.: US 2026/0344286 A1
(43) Pub. Date: Oct. 29, 2026

(54) ADAPTIVE LIQUID COOLING SYSTEM FOR CHIP PACKAGE

(71) Applicant: Taiwan Semiconductor Manufacturing Company, Ltd., Hsinchu (TW)

(72) Inventors: Chien-Chang Wang, Hsinchu City (TW); Kuan-Min Wang, Hsinchu City (TW); Ching Wang, Taichung City (TW); Kuo-Chin Chang, Chiayi City (TW); Kathy Wei Yan, Hsinchu (TW); Jun He, Zhubei City (TW)

(21) Appl. No.: 19/732,631

(22) Filed: Jul. 7, 2026

Related U.S. Application Data
(62) Division of application No. 18/630,160, filed on Apr. 9, 2024.
(60) Provisional application No. 63/615,811, filed on Dec. 29, 2023.

(51) Int. Cl. H10N 10/13; H10N 10/01; H10N 10/17; H10W 40/22; H10W 40/28; H10W 40/47

(52) U.S. Cl. CPC H10N 10/13; H10N 10/01; H10N 10/17; H10W 40/22; H10W 40/28; H10W 40/47

(57) ABSTRACT

A liquid cooling system includes a thermoelectric cooler (TEC) between a radiator plate and a radiator, and a thermoelectric generator (TEG) at a location where the TEG is driven by heat from a chip package. The chip package is cooled by a cold plate of the liquid cooling system and the TEC is controlled by the TEG. The TEG may be between the chip package and the cold plate or elsewhere in or adjacent to the chip package. The TEG may control the TEC through a relay. The TEG automatically activates the TEC when the chip package is under peak load.

### REFERENCE TO RELATED APPLICATIONS

This Application is a Divisional of U.S. application Ser. No. 18/630,160, filed on Apr. 9, 2024, which claims the benefit of U.S. Provisional Application No. 63/615,811, filed on Dec. 29, 2023. The contents of the above-referenced Patent Applications are hereby incorporated by reference in their entirety.

### BACKGROUND

As semiconductor technology continues to advance, there is an ever-increasing demand for higher-performance devices with smaller form-factors. As part of the solution for meeting these demands, a plurality of substrates may be vertically stacked within a chip package. Higher-performance, smaller form-factor, and vertical stacking all make thermal management more difficult. Heat, if not properly managed, can degrade the performance of integrated circuit (IC) devices, reduce their lifespan, or even cause catastrophic failure. Existing thermal management techniques include the use of heat sinks, fans, and thermal interface materials (TIMs). Some of the highest performing cooling systems are liquid cooling systems.

### BRIEF DESCRIPTION OF THE DRAWINGS

Aspects of the present disclosure are best understood from the following detailed description when read with the accompanying figures. In accordance with standard industry practice, features are not drawn to scale. Moreover, the dimensions of various features within individual drawings may be arbitrarily increased or reduced relative to one-another to facilitate illustration or provide emphasis.

FIG. 1 illustrates a cross-sectional view of a system having a chip package cooled according to an embodiment of the present disclosure.

FIGS. 2A and 2B illustrate a relay that may be used in some embodiments of the present disclosure.

FIG. 3 illustrates a cross-sectional view of thermoelectric module in accordance with an embodiment of the present disclosure.

FIG. 4 is a perspective view of a thermoelectric module in accordance with an embodiment of the present disclosure.

FIG. 5 illustrates a thermoelectric module connected as a thermoelectric cooler (TEC).

FIG. 6 illustrates a thermoelectric module connected as a thermoelectric generator (TEG).

FIGS. 7-10 illustrate arrangements of thermoelectric modules according to various embodiments of the present disclosure.

FIG. 11 illustrates a cross-sectional view of a system having a chip package cooled according to another embodiment of the present disclosure.

FIGS. 12-13 illustrate arrangements of thermoelectric modules according to various embodiments of the present disclosure.

FIGS. 14-15 illustrate cross-sectional views of systems having chip packages cooled according to some other embodiments of the present disclosure.

FIG. 16A illustrates a cross-sectional view of a system having a chip package cooled according to another embodiment of the present disclosure.

FIG. 16B illustrates a cross-sectional view of a chip in the system of FIG. 16A.

FIGS. 17-18 illustrate cross-sectional views of systems having chip packages cooled according to some other embodiments of the present disclosure.

FIGS. 19-20 provide flow charts of processes in accordance with various embodiments of the present disclosure.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact.

Spatially relative terms, such as “beneath,” “below,” “lower,” “above,” “upper”, and the like, may be used herein to describe one element or feature's relationship to another element(s) or feature(s) as illustrated in the figures. These spatially relative terms are intended to encompass different orientations of the device or apparatus in use or operation in addition to the orientation depicted in the figures. The device or apparatus may be otherwise oriented (rotated 90 degrees or at other orientations) and the spatially relative descriptors used herein may be interpreted accordingly. Terms “first”, “second”, “third”, “fourth”, and the like are merely generic identifiers and, as such, may be interchanged in various embodiments. For example, while an element (e.g., an opening) may be referred to as a “first” element in some embodiments, the element may be referred to as a “second” element in other embodiments.

The present disclosure relates to a liquid cooling system that includes a cold plate, a radiator, and a pump. The radiator and the cold plate have internal passages and may be interconnected through fluid conduits, which may be hoses or the like. The pump circulates fluid through and between the radiator and the cold plate so that heat is carried from the cold plate to the radiator. The cold plate is placed in thermal contact with a chip package so as to cool the chip package. The radiator draws heat from the fluid and releases the heat to the surrounding environment. A fan may be directed at the radiator to increase the efficiency with which the radiator releases heat.

Although liquid cooling systems of this type are among the most effective, a liquid cooling system may not provide adequate heat removal from a chip package during periods of peak load. This is particularly likely to occur if the liquid circulation rate within the liquid cooling system has diminished due to age-related deterioration or some other factor.

One aspect of the present disclosure is an enhanced liquid cooling system that includes a thermoelectric cooler (TEC) between a radiator plate and a radiator. The coolant circulates through the radiator plate. When provided with power, the TEC drives the radiator plate temperature below the radiator temperature so that a temperature of the cooling fluid can be driven below an ambient temperature. The TEC enhances the liquid cooling system without significantly increasing an amount of space taken up by the liquid cooling system. In some embodiments, the TEC extends over from about 70% to about 100% of an interfacial area between the radiator plate and the radiator. A higher coverage provides more efficient cooling. Most of the benefit can be realized if the area coverage is 70% or greater.

Another aspect of the invention is a method of operation in which the TEC, or some other liquid cooling system enhancement, is operated selectively during periods of peak load. A period of peak load might be one in which the chip package is producing heat above a threshold rate. Periods of peak load may comprise only a small fraction of the operating cycle of the chip package. Limiting operation of the TEC to periods of peak demand can greatly reduce the power consumption of the liquid cooling system.

One approach to limiting operation of the TEC to periods of peak load is to measure a temperature of the chip package and operate the TEC selectively according to whether the measured temperature exceeds a threshold. A difficulty with that approach is that a range of temperatures exist within the chip package, particularly if the chip package is of the type that includes a plurality of device layers. A peak temperature occurs at a hot spot within the interior of the package. The temperature may be measured at a location nearer the outside of the chip package than the hot spot, and therefore the measured temperature may have a value intermediate between that of the hot spot and that of the cold plate. The cold plate temperature is variable, so the measured temperature may not accurately track the hot spot temperature.

In accordance with another aspect of the present disclosure, the TEC or another liquid cooling system enhancement is selectively activated in response to a temperature differential exceeding a threshold. The temperature differential may be any temperature differential driven by heat from the chip package. A temperature differential tracks the need for enhanced cooling more accurately than the measured temperature referred to in the preceding paragraph. If the heat generation rate within the chip package doubles, all the temperature gradients in and around the chip package will approximately double. If the coolant circulation rate drops and the chip package beings to heat up, the temperature gradients within and around the chip package will increase so that the enhanced cooling system is reliably triggered.

In some embodiments, the temperature differential is not measured. In some embodiments, the enhancement of the liquid cooling system is activated by a thermoelectric generator (TEG). The TEG may be installed at any location where the TEG is driven by heat from the chip package. In some embodiments, the TEG is installed between the cold plate and the chip package. The pathway from the chip package to the cold plate is the pathway for most of the heat released by the chip package. Placing the TEG along this pathway helps ensure that the TEG receives enough heat to generate a strong signal.

In some embodiments, the TEG extends across an area between the chip package and the cold plate. The TEG may act to some degree as an insulating barrier. Accordingly, in some other embodiments the TEG extends across only a fraction of the area between the chip package and the cold plate. The remaining area may be filled by a thermally conductive structure lateral to the TEG. In particular, the thermally conductive structure lateral to the TEG may be positioned between a hot spot in the chip package and the cold plate. The conductive structure may be designed so that more heat passes from the cold plate to the chip package through the thermally conductive structure than through the TEG.

In some embodiments, the TEG extends over 100% of an interfacial area between the chip package and the cold plate. In some embodiments, the TEG extends over only a fraction of that area, e.g., from about 10% to about 90% of the area. In some embodiments, the TEG extends over 30% or less of the area. A larger TEG area coverage helps to assure that the output current will be sufficient to close a relay. A smaller TEG area allows for more efficient cooling. If the TEG area fraction is 30% or less, the insulating effect of the TEG will generally be small enough to not significantly reduce the overall thermal performance.

The coolant temperature increases as it passes through the cold plate. As a consequence, the coolant temperature may vary across the cold plate between a coolant inlet and a coolant outlet. In embodiments where the TEG extends across only a fraction of the area between the chip package and the cold plate, the TEG may be positioned so that it is between the chip package and the cold plate where the cold plate is coldest, which is an area adjacent the coolant inlet. Placing the TEG at this location helps assure the TEG experiences a large enough temperature gradient to generate a strong signal.

In some embodiments, the output of the TEG controls a relay. In some of these embodiments, the TEG is connected to the coil of the relay so that the relay is closed in response to the TEG output reaching a threshold level. A cooling enhancement such as a TEC may be powered through the relay. This provides a reliable structure for selectively engaging the cooling enhancement in relationship to the requirements of the chip package.

The TEG may be configured relative to the relay so as to provide a suitable voltage and sufficient current for closing the relay when the predetermined temperature differential is reached. For this purpose, it is useful to provide the TEG as a plurality of thermoelectric modules. The voltages of the thermoelectric modules will vary in proportion to the temperature differential. A group of thermoelectric modules may be connected in series so that the voltage output matches the relay's coil voltage specification when the temperature differential is reached. Additional thermoelectric modules may be connected in parallel to provide a sufficient current to switch the relay. The thermoelectric modules may be arrayed across the cold plate.

In some embodiments, the predetermined temperature differential at which the TEG closes the relay is in the range from about 10 C to about 100 C. In some embodiments, the predetermined temperature differential is at least about 30 C. In some embodiments, the predetermined temperature differential is at least about 60 C. A lower threshold keeps the chip package temperature in a narrower range. A higher threshold saves power.

In some embodiments, the relay's coil voltage specification is in the range from about 1 V to about 10 V. In some embodiments, the relay's coil voltage specification is about 5V or less. In some embodiments, the relay's coil voltage specification is about 1.5V. In some embodiments, the relay's coil voltage specification is about 3V. Lower voltage specifications allow the use of smaller TEGs. Specifying standard voltages such as 1.5 V or 3V allows the use of less expensive relays.

In some embodiments, the TEC is provided by a plurality of thermoelectric modules. A group of the thermoelectric modules is connected in series so as to provide a predetermined temperature differential at the voltage level of the power source, which may be the power source connected and disconnected by the relay. Additional thermoelectric modules may be connected in parallel to increase the overall cooling capacity. The thermoelectric modules may be arrayed across a face of the radiator plate. In some embodiments, the thermoelectric modules are disposed on two opposite faces of the radiator plate so as to increase the overall amount of cooling. A second radiator and/or a second fan may be placed over the second face. It should be noted that a thermoelectric module may be configured as either a TEC or a TEG, the difference being that for a TEG the thermoelectric module is coupled to a load and for a TEC the thermoelectric module is coupled to a power source.

In some embodiments, the TEG abuts a metal lid over the chip package. The metal lid helps to spread heat. In some embodiments, the TEG is integrated into the lid. In some embodiments, the TEG is inside the lid. In some embodiments, the TEG is installed between a motherboard and the chip package. In some embodiments, the TEG is installed inside the chip package.

The TEG may be disposed at a location intermediate between a hot spot within the chip package and the cold plate, but generally does not span the entire distance between the hot spot and the cold plate. Accordingly, the temperature difference between a hot side and a cold side of the TEG maybe less than a temperature difference between a hot spot within the chip package and the cold plate. In some embodiments, the temperature difference between the hot side and the cold side is in the range from about 10% to about 90% of the temperature difference between the hot spot within the cold plate. In some embodiments, the temperature difference between the hot side and the cold side is at least about 30% of the temperature difference between the hot spot within the cold plate. If the temperature difference is too small, the TEG may not provide enough power to control a relay without amplification. In some embodiments, the temperature difference between the hot side and the cold side is about 50% or less of the temperature difference between the hot spot within the cold plate. The smaller temperature difference results from using a practical location for the TEG and also helps characterize the difference between a TEG designed for power harvesting and a TEG designed for control according to the present disclosure.

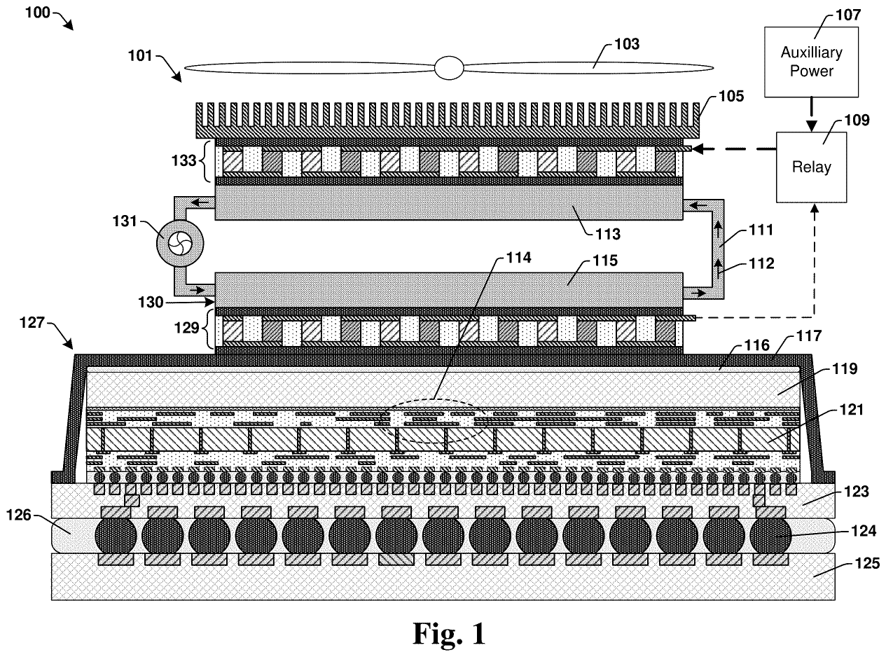

FIG. 1 illustrates a cross-sectional view of a system 100 in accordance with some embodiments. The system 100 includes a chip package 127 and a liquid cooling system 101. The chip package 127 is covered by a lid 117 and may be mounted on a motherboard 125. The liquid cooling system 101 includes a fan 103, a radiator 105, a TEC 133, a radiator plate 113, tubing 111, a pump 131, a cold plate 115, a TEG 129, and a relay 109. The radiator plate 113 and the cold plate 115 have internal fluid passages (not shown) connected by the tubing 111 and containing a fluid 112. The pump 131 circulates the fluid 112 between the radiator plate 113 and the cold plate 115. The TEG 129 is between the cold plate 115 and the lid 117 and abuts both the cold plate 115 and the lid 117. The TEC 133 is between the radiator plate 113 and the radiator 105 and abuts both the radiator plate 113 and the radiator 105. A fan 103 is positioned to drive an air flow past the radiator 105.

The fan 103 and the pump 131 may be powered by a first power source (not shown). The TEC 133 is selectively connected to an auxiliary power supply 107 through a relay 109. The auxiliary power supply 107 may be the same or different from the first power source. The TEG 129 is connected to the relay 109 so that the TEG 129 closes the relay 109 when a temperature difference between the lid 117 and the cold plate 115 reaches a predetermined threshold. The threshold is predetermined by the structure of the TEG 129.

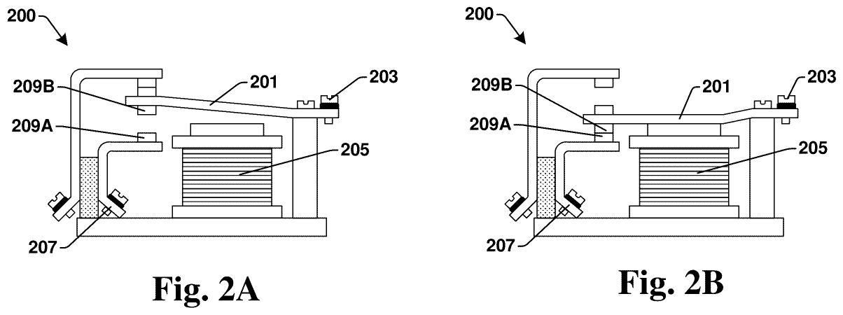

FIGS. 2A and 2B provide cross-sectional views of a relay 200 in open and closed positions respectively. The relay 200 may be used as the relay 109 in the system 100 of FIG. 1. The relay 200 has a coil 205. When the coil 205 is energized, it draws a spring arm 201 downward so as to bring a first contact 209A and a second contact 209B into abutment. The spring arm 201 deflects upward when the coil 205 is deenergized, causing the first contact 209A and the second contact 209B to move apart. The first contact 209A and the second contact 209B form a selective connection between a first terminal 203 and a second terminal 207. One of the first terminal 203 and the second terminal 207 may be connected to the auxiliary power supply 107 and the other may be connected to the TEC 133 (see FIG. 1). The coil 205 may be powered by the TEG 129 (see FIG. 1).

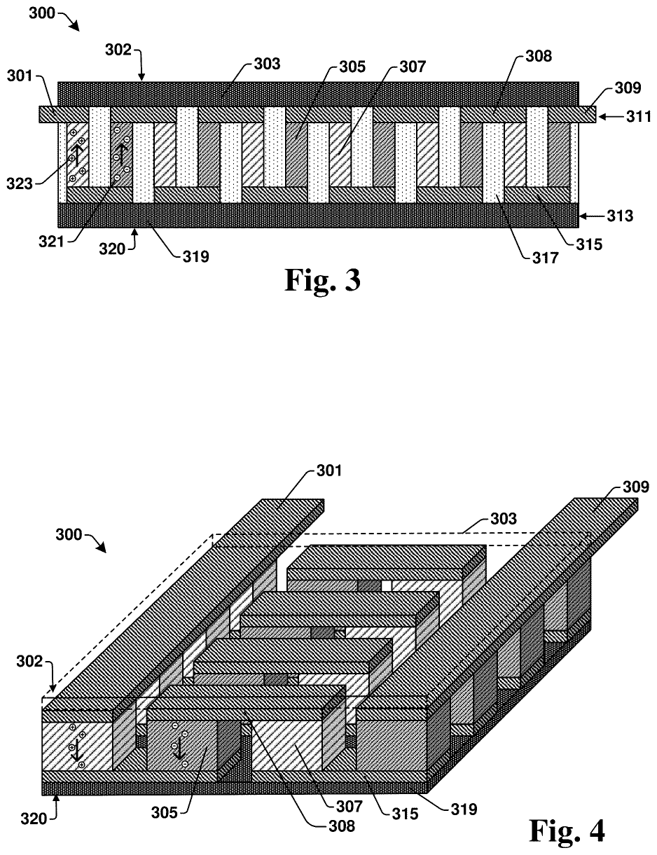

FIG. 3 illustrates a cross-sectional view of a thermoelectric module 300 that may provide either the TEC 133 or the TEG 129 of FIG. 1. The thermoelectric module 300 includes a hot side plate 319, first wires 315 in a first wiring layer 313, N-type vias 305, P-type vias 307, a dielectric 317, second wires 308 in a second wiring layer 311, and a cold side plate 303. The N-type vias 305 and the P-type vias 307 are semiconductors with P-type doping and N-type doping respectively.

FIG. 4 illustrates a perspective view of the thermoelectric module 300 with the dielectric 317 cut away and the cold side plate 303 shown in outline. As can be seen in FIG. 4, the first wires 315 and the second wires 308 connect groups of the N-type vias 305 and the P-type vias 307 in series between a first lead 301 and a second lead 309. When current flows from the first lead 301 to the second lead 309, it flows from the N-type vias 305 to the P-type vias 307 on the cold side 302. The charge carriers passing between the N-type vias 305 and the P-type vias 307 on the cold side 302 absorb heat so as to produce a cooling effect. The charge carriers passing between the P-type vias 307 and the N-type vias 305 on the hot side 320 release the absorbed heat. In the N-type vias 305, heat is carried from the cold side 302 to the hot side 320 by a flow of electrons 321. In the P-type vias 307, heat is carried from the cold side 302 to the hot side 320 by a flow of holes 323.

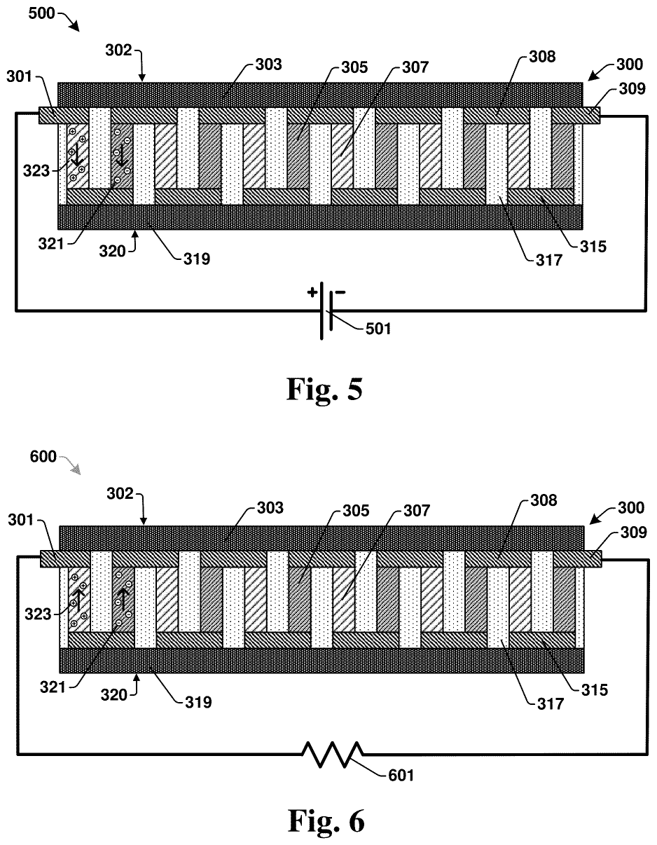

FIG. 5 provides a cross-sectional view 500 of the thermoelectric module 300 configured as a TEC. The thermoelectric module 300 is configured as a TEC by connecting the first lead 301 and the second lead 309 of the thermoelectric module 300 to a DC power source 501. The DC power source 501 may be the auxiliary power supply 107 (see FIG. 1). The DC power source 501 drives a temperature difference between the hot side 320 and the cold side 302.

FIG. 6 provides a cross-sectional view 600 of the thermoelectric module 300 configured as a TEG. The thermoelectric module 300 is configured as a TEG by connecting the first lead 301 and the second lead 309 to a load 601. The load 601 may be the coil 205 of the relay 200 (see FIGS. 2A and 2B). A temperature difference between the hot side 320 and the cold side 302 drives the load 601.

With reference to FIG. 4, the thermoelectric module 300 may include both series and parallel connections between groups of the N-type vias 305 and the P-type vias 307. In the case of a TEG, series connections increase the voltage output for a given temperature differential between the hot side 320 and the cold side 302. Parallel connections increase the current of the output. In the case of a TEC, series connections increase the temperature differential between the hot side 320 and the cold side 302 generated by a given power supply voltage and parallel connections increase the overall cooling capacity. Accordingly, the thermoelectric module 300 may be constructed to meet the design specifications for either the TEC 133 or the TEG 129. In practice, however, it can be more economical to construct the TEC 133 and/or the TEG 129 using pluralities of thermoelectric module 300 manufactured in bulk according to a specification set independently from the present application. The plurality of thermoelectric modules 300 may then be joined with whatever combination or series and parallel connections meets the specification for the TEC 133 or the TEG 129.

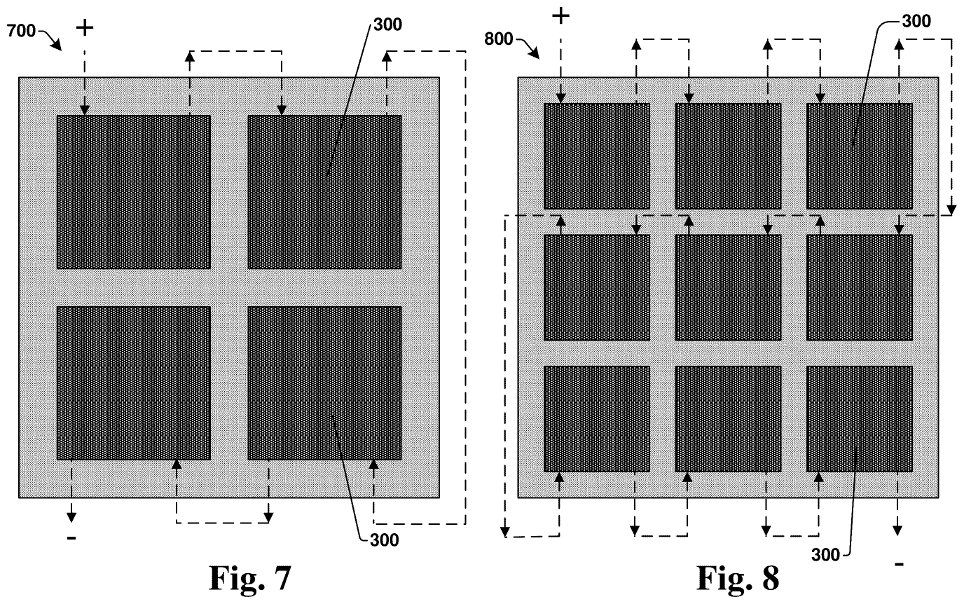

FIG. 7 provides a top layout view of a thermoelectric device 700 that may provide either the TEC 133 or the TEG 129. The thermoelectric device 700 includes four thermoelectric modules 300 connected in series. If the first lead 301 and the second lead 309 are connected to a load, the voltage output will be four times that of a single thermoelectric module 300. This arrangement would be suitable for operating the coil 205 (see FIG. 1) at a voltage that is four times the voltage produced by each thermoelectric module 300 at the threshold temperature differential. If the first lead 301 and the second lead 309 are connected to a power supply, the temperature differential produced would be that provided by each thermoelectric module 300 at one fourth the applied voltage.

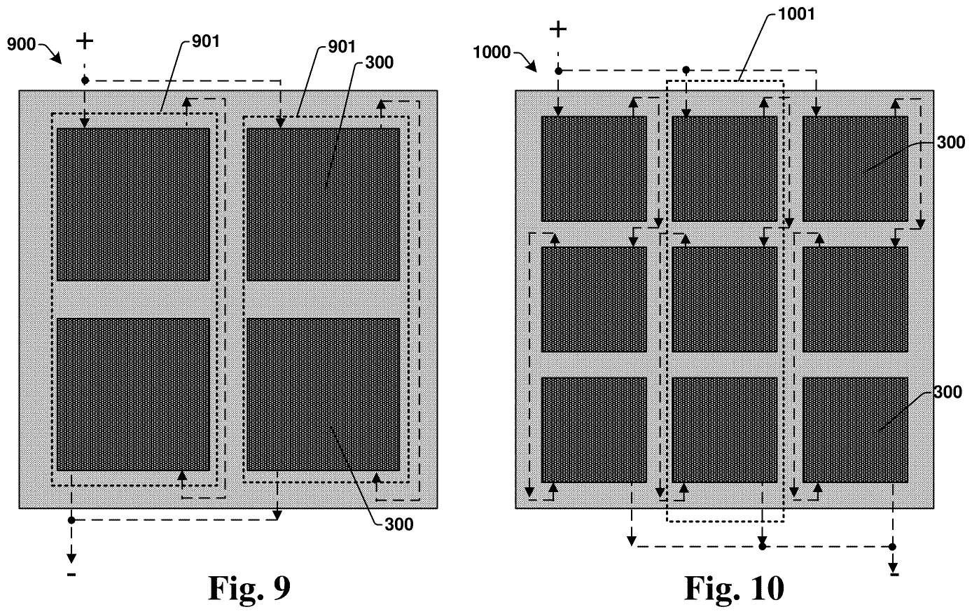

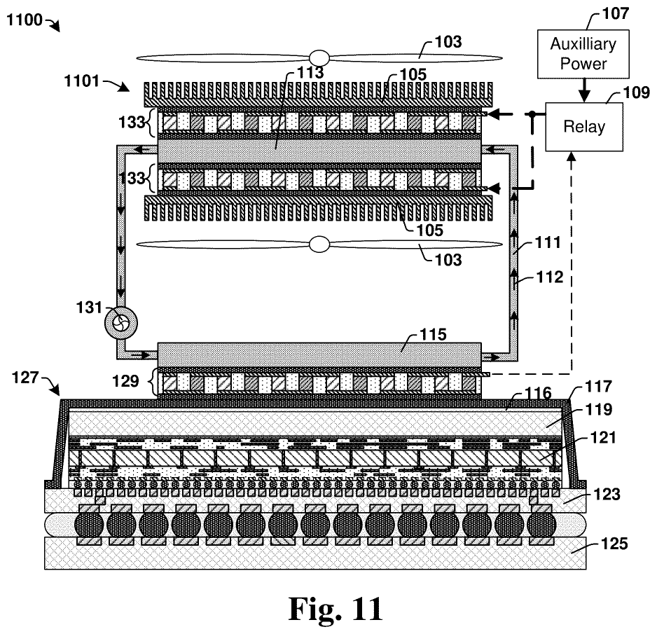

FIG. 8 provides a top layout view of a thermoelectric device 800, which may also be used as either the TEC 133 or the TEG 129. The thermoelectric device 800 includes nine thermoelectric modules 300 connected in series. If the first lead 301 and the second lead 309 are connected to a load, the voltage output will be nine times that of a single thermoelectric module 300. This arrangement provides a voltage that is nine times the voltage produced by each thermoelectric module 300 at any given temperature differential. If the first lead 301 and the second lead 309 are connected to a power supply, the temperature differential produced would be that provided by each thermoelectric module 300 at one ninth the applied voltage.

For the TEG 129, the target voltage may be a voltage rating for the coil 205. Series connected groups of the thermoelectric modules 300, each providing an output that meets the voltage rating at the threshold temperature differential, may be combined so that the current provided at the threshold temperature differential is sufficient to close the relay 200 (see FIGS. 2A-2B). For the TEC 133, groups of the thermoelectric modules 300 may be connected in series to meet a targeted temperature differential. A plurality of these series connected groups may be provided to meet the overall cooling requirement. In terms of choosing the target temperature differential, a lower temperature differential provides more efficient use of power provided for cooling, but less overall cooling capacity. A larger temperature differential provides less efficient use of power but allows greater cooling to be achieved. The target temperature differential may be selected to provide a balance between these two effects. The target temperature differential may also be limited to avoid freezing the fluid 112. Although refrigerants with a variety of freezing points may be used, in some embodiments, the fluid is water (H₂O). Water is easy to handle and has a larger specific heat than most refrigerants.

FIG. 9 provides a top layout view of a thermoelectric device 900 that may provide either the TEC 133 or the TEG 129. The thermoelectric device 900 includes four thermoelectric modules 300 in two groups 901. Within each group 901, two thermoelectric modules 300 are connected in series. The two groups 901 are connected in parallel.

FIG. 10 provides a top layout view of a thermoelectric device 1000, which may also be used as either the TEC 133 or the TEG 129. The thermoelectric device 1000 includes nine thermoelectric modules 300 in three groups 1001. Within each group 1001, three thermoelectric modules 300 are connected in series. The three groups 1001 are connected in parallel.

For the TEC 133, adding more thermoelectric modules 300 is desirable in terms of increasing potential cooling capacity. A constraint on the number of thermoelectric modules 300 that can be added may be the area of the radiator plate 113 (see FIG. 1).

FIG. 11 illustrates a cross-sectional view of a system 1100 in which the chip package 127 is paired with a liquid cooling system 1101. The liquid cooling system 1101 is like the liquid cooling system 101 of FIG. 1, except that the liquid cooling system 1101 has two TECs 133, two radiators 105, and two fans 103 arranged on opposite sides faces of the radiator plate 113. The liquid cooling system 1101 may have approximately double the cooling power of the liquid cooling system 101. Both the TECs 133 may be controlled by the TEG 129 through the relay 109.

For the TEG 129, adding more thermoelectric modules 300 is not necessarily desirable. Once the output of the TEG 129 is sufficient to close the relay 109 (see FIG. 1), adding more thermoelectric modules 300 has little benefit. Moreover, the TEG 129 can act as an insulating layer.

FIG. 12 provides a top layout view of a thermoelectric device 1200 that may provide the TEG 129. The thermoelectric device 1200 includes eight thermoelectric modules 300. In a central area, which may be positioned over a hot spot 114 in the chip package 127 (see FIG. 1), there is a thermally conductive block 1201. The thermally conductive block 1201 may have the same thickness as the thermoelectric modules 300 and is composed of a material with high thermal conductivity. The material may be a metal, a high thermal conductivity dielectric, a very high thermal conductivity dielectric, or an extremely high thermal conductivity dielectric.

In the present disclosure, a high thermal conductivity dielectric has a thermal conductivity of at least about 10 Watts per meter-Kelvon (W/m-K). By comparison, silicon dioxide (SiO₂) has a thermal conductivity in the range from about 1.1 W/m-K to about 1.4 W/m-K. Crystalline silicon nitride (Si₃N₄) is an example of a high thermal conductivity dielectric and may have a thermal conductivity as high as 29 W/m-K. The silicon nitride (Si₃N₄) commonly found in semiconductor devices is amorphous and has a thermal conductivity in the range from about 2 W/m-K to about 5 W/m-K. The amorphous form is ordinarily produced because it lends itself to higher deposition rates than does the crystalline form. Also, the lower dielectric constant of the amorphous form is usually sought after when forming dielectrics for semiconductor devices. Thermal conductivity may vary continuously with degree of crystallinity between the purely amorphous form and a purely crystalline form.

A very high thermal conductivity dielectric has a thermal conductivity higher than purely crystalline silicon nitride (Si₃N₄), in other words, higher than 29 W/m-K. In some embodiments, the very high thermal conductivity dielectric has a thermal conductivity of at least about 100 W/m-K. Examples of dielectrics having a thermal conductivity of at about 100 W/m-K or more include, without limitation, aluminum nitride (AlN), crystalline boron nitride (BN), crystalline boron phosphide (BP), crystalline boron arsenide (BAs), hexagonal boron nitride (hBN), graphene, diamond, and the like. Among these examples, aluminum nitride (AlN), boron nitride (BN), boron phosphide (BP), and boron arsenide (BAs) have amorphous forms, crystalline forms, and forms of intermediate crystallinity. Forms with sufficient crystallinity are extremely high thermal conductivity dielectrics. With regard to the hexagonal compounds, which include hexagonal boron nitride (hBN) and graphene, the thermal conductivity depends on the form. The lateral forms (sheets) generally provide the highest thermal conductivity. An extremely high thermal conductivity dielectric has a thermal conductivity of at least about 1000 W/m-K or more. This can be achieved, for example, with boron arsenide (BAs), one of the carbon-based dielectrics described above, or the like.

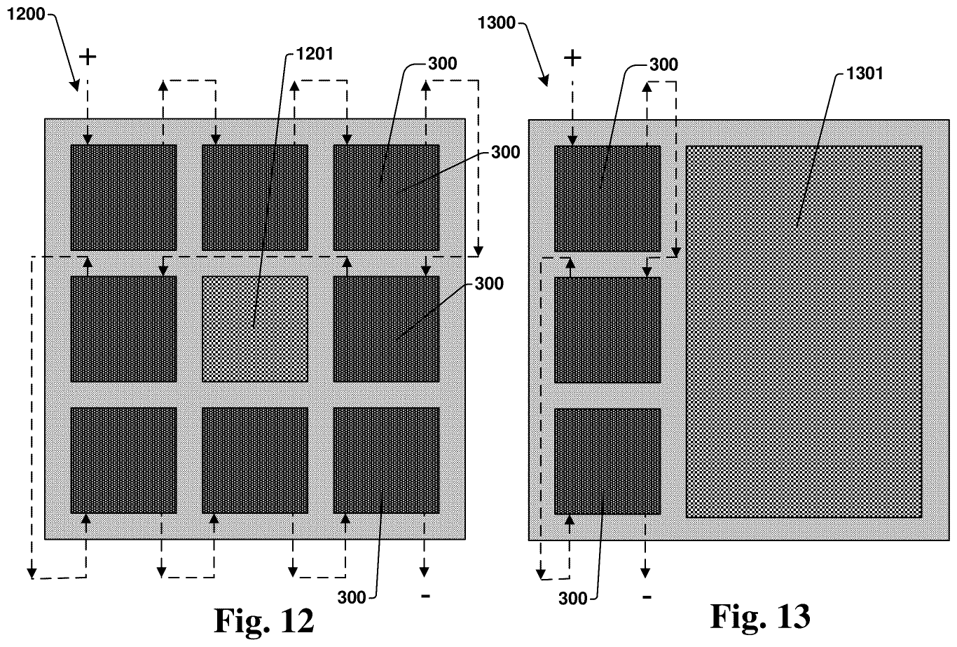

Another consideration for placing the thermoelectric modules 300 is that the fluid 112 heats as to moves through the cold plate 115 so that the thermoelectric modules 300 experience a larger temperature gradient and produce more power when they are proximate an inlet side 130 of the cold plate 115 (see FIG. 1). FIG. 13 provides a top layout view of a thermoelectric device 1300 that may provide the TEG 129. The thermoelectric device 1300 includes three thermoelectric modules 300 positioned to be proximate the inlet side 130 (see FIG. 1). An area over the cold plate 115 and lateral to the thermoelectric modules 300 is occupied by a thermally conductive block 1301. The thermally conductive block 1301 may be like the thermally conductive block 1201 of FIG. 12 except for differences in size and location.

Returning to FIG. 3, N-type vias 305 are a semiconductor material having a high thermoelectric figure of merit and N-type doping. A high thermoelectric figure of merit is 1.0 or greater. The greater the thermoelectric figure of merit, the greater the efficiency of the resulting thermoelectric cooler. Examples of semiconductor materials having a high thermoelectric figure include bismuth telluride-based compounds (BiTe—), antimony telluride-based compounds (SbTe—), antimony bismuth telluride-based compounds (Bi_{2-y}Sb_{y}Te—), lead telluride (PbTe), silicon germanium (SiGe), skutterudite compounds, zinc antimonide (Zn₃Sb₃), germanium telluride (GeTe), half-Heusler compounds, the like, and others. Examples of bismuth telluride-based compounds include Bi₂(TeₓSe₁₋ₓ)₃ and the like. Examples of antimony telluride-based compounds include Sb₂(TeₓSe₁₋ₓ)₃ and the like. Examples of antimony bismuth telluride-based compounds include Bi_{2-y}Sb_{y}(TeₓSe₁₋ₓ)₃ and the like. In these formulas, x and y can independently have any values from 0 to 1. Examples of skutterudite compounds include cobalt antimonide (CoSb₃) and the like. Examples of half-Heusler compounds include hafnium nickel stannide (HfNiSn), zirconium nickel stannide (ZrNiSn), and the like. The N-type dopant may be, for example, phosphorous (P), arsenic (As), antimony (Sb), or the like.

In some embodiments, the semiconductor material includes a nanostructure that increased the thermoelectric figure of merit. Using nanostructures, the thermoelectric figure of merit may be increased to 2.0 or greater. Examples of nanostructures include quantum dots and superlattices. Quantum dots may be nanoparticles of a semiconductor cadmium selenide (CdSe), cadmium telluride (CdTe), lead sulfide (PbS), indium arsenide (InAs), or the like. These more expensive structures are particularly suitable for the thermoelectric modules 300 used for the TEG 129 and other TEGs described herein, particularly in those embodiments where a small size or functionality with a small temperature gradient is particularly advantageous.

The P-type vias 307 are a semiconductor material having a high thermoelectric figure of merit and P-type doping. The P-type dopant may be, for example, boron (B), aluminum (Al), gallium (Ga), indium (In), or the like. The P-type vias 307 and the N-type vias 305 may be different semiconductor materials in addition to being semiconductors having different doping types.

The dielectric 317 is disposed between the P-type vias 307 and the N-type vias 305. This dielectric 317 may be silicon dioxide (SiO₂) or the like, a low-k dielectric, or an extremely low-k dielectric. The first wires 315 and the second wires 308 may be a metal or some other conductive material. The metal may be, for example, copper (Cu), tungsten (W), ruthenium (Ru), palladium (Pd), platinum (Pt), cobalt (Co), nickel (Ni), zirconium (Zi), titanium (Ti), tantalum (Ta), aluminum (Al), conductive carbides, oxides, alloys of these metals, or the like.

The hot side plate 319 and the cold side plate 303 are composed of materials selected to have high thermal conductivity and may include one or more layers of any suitable materials. For the hot side plate 319, at least a layer closest to the first wires 315 is a dielectric layer. For the cold side plate 303, at least a layer closest to the second wires 308 is a dielectric layer. The layer may be metals, high thermal conductivity dielectrics, very high thermal conductivity dielectrics, or extremely high thermal conductivity dielectrics. In some embodiments, the hot side plate 319 and/or the cold side plate 303 comprises a very high thermal conductivity dielectric. In some embodiments, the hot side plate 319 and/or the cold side plate 303 comprises an extremely high thermal conductivity dielectric. In some embodiments, the hot side plate 319 and/or the cold side plate 303 comprises graphite. In addition to having an extremely high thermal conductivity dielectric, graphite has the advantage of being soft in a way that promotes good thermal contact with adjacent structures.

Returning to FIG. 1, the chip package 127 includes a semiconductor substrate 121 and may further include additional substrate layers such as a carrier substrate 119 and a redistribution layer 123. A semiconductor substrate may be a bulk semiconductor substrate or a semiconductor on insulator (SOI) substrate. At least an upper portion of a semiconductor substrate is a semiconductor. The semiconductor may be silicon (Si), a group III-V semiconductor (e.g., GaAs) or some other binary semiconductor, a tertiary semiconductor (e.g., AlGaAs), a higher order semiconductor, the like, or any other suitable semiconductor. The carrier substrate 119 may also be a semiconductor substrate. Various semiconductor devices are formed on or in the semiconductor substrate 121. These may include transistors (such as complementary metal oxide field effect transistors (MOSFETs), fin field effect transistors (finFETS), or the like), diodes, capacitors, memory cells, thyristors, resistors, the like, or any combination thereof.

The redistribution layer 123 and the motherboard 125 may comprise dielectric substrates. A dielectric substrate may be, for example, an organic polymer substrate, the like, or some other suitable dielectric material. Examples of organic polymer substrate materials include, without limitation, polyimide, polytetrafluoroethylene, epoxies, and the like. An epoxy may be one formed from Bismaleimide-Triazine resin (BT-resin), some other epoxy resin, or the like. A dielectric substrate may be a laminate and may be reinforced with glass cloth, fiberglass, or the like.

The chip package 127 may be attached to the motherboard 125 by an array of solder balls 124, which form a ball grid array (BGA). The solder balls 124 may be surrounded by a thermal paste 126 to improve heat transfer between the chip package 127 and the motherboard 125. A thermal paste 116 may also be disposed between the lid 117 and the chip package 127. Thermal paste may also be used between the lid 117 and the TEG 129, between the TEG 129 and the cold plate 115, between the radiator plate 113 and the TEC 133, and between the TEC 133 and the radiator 105.

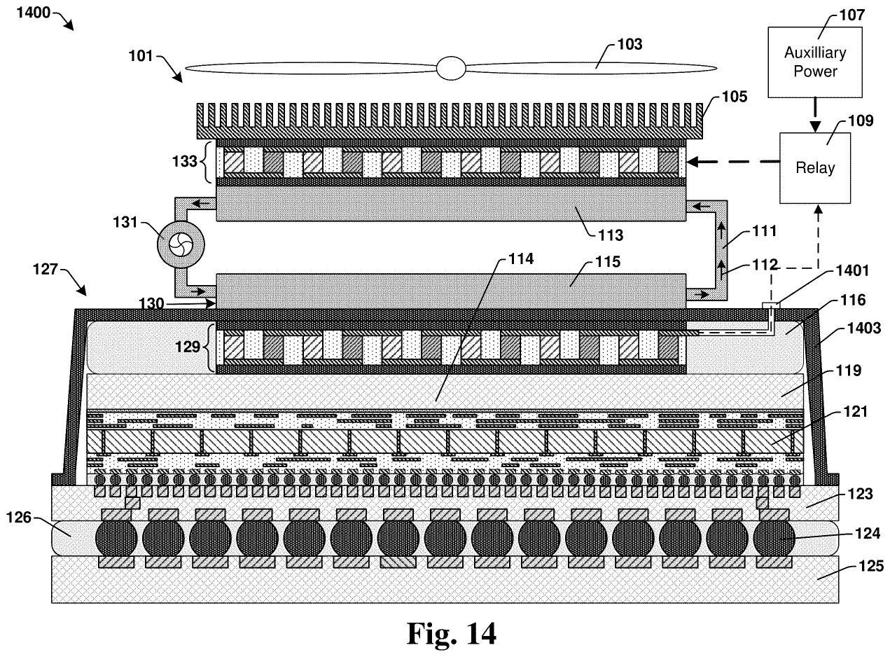

FIG. 14 illustrates a system 1400 in accordance with another embodiment. The system 1400 includes a chip package 127 with a liquid cooling system 101. The liquid cooling system 101 is like the liquid cooling system 101 of FIG. 1 except that in the liquid cooling system 101 the TEG 129 is incorporated into a lid 1403 that takes the place of the lid 117 used in the system 100 of FIG. 1. The TEG 129 may be incorporated into the lid 1403 so as to be within the lid 1403. In the illustrated position, the TEG 129 may experience a large temperature gradient while the lid 1403 spreads heat in such a way as to ensure sufficient cooling of the chip package 127. A contact pad 1401 may be formed on the lid 1403 to facilitate connecting the TEG 129 to the relay 109.

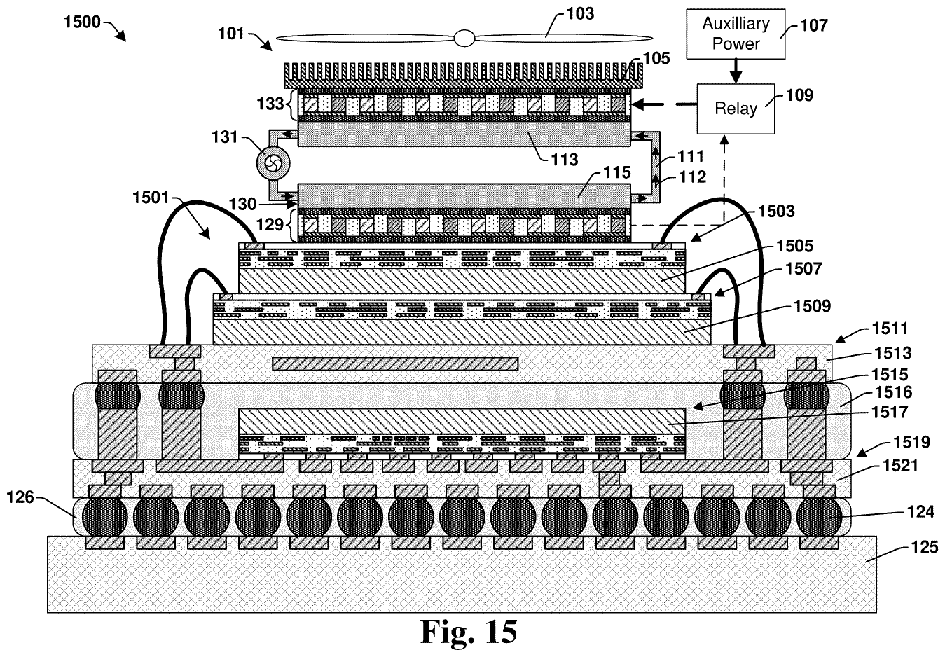

FIG. 15 illustrates a system 1500 in accordance with another embodiment. The system 1500 includes a chip package 1501, the liquid cooling system 101, and a motherboard 125. The chip package 1501 comprises a plurality of device layers including a first routing layer 1519, a first chip 1515, a second routing layer 1511, a second chip 1507, and a third chip 1503. Each of these device layers includes a substrate. The first routing layer 1519 comprises a first package substrate 1521. The first chip 1515 comprises a first semiconductor substrate 1517. The second routing layer 1511 comprises a second package substrate 1513. The second chip 1507 comprises a second semiconductor substrate 1509. The third chip 1503 comprises a third semiconductor substrate 1505. A high thermal conductivity underfill 1516 may fill space between the second routing layer 1511 and the first chip 1515. The TEG 129 may be in direct contact with the uppermost device layer, which is the third chip 1503.

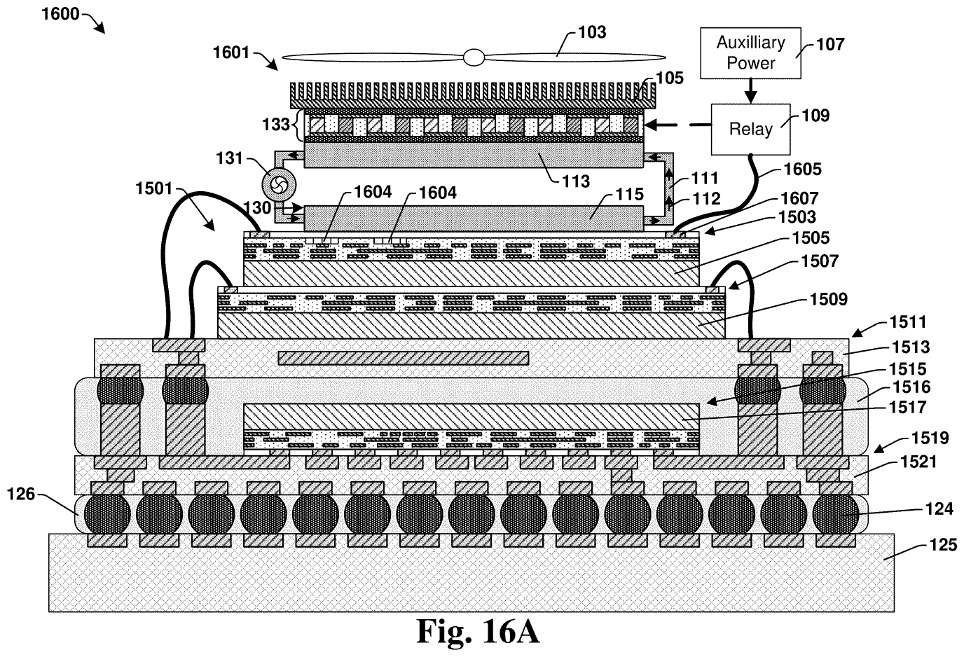

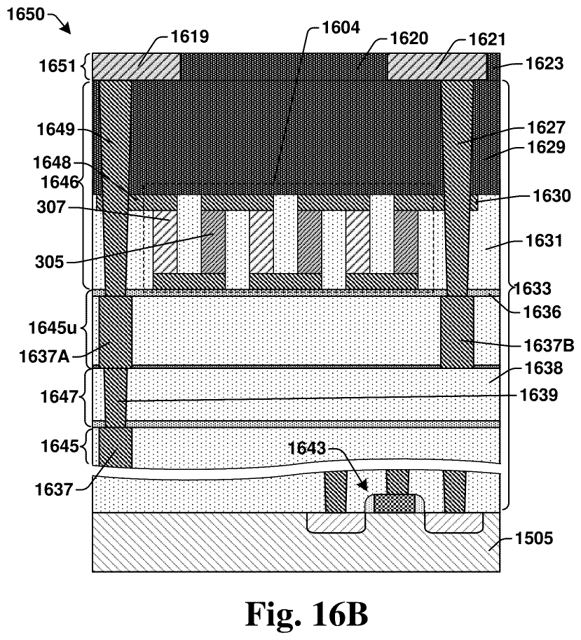

FIG. 16A illustrates a system 1600 in accordance with another embodiment. The system 1600 includes the chip package 1501, a liquid cooling system 1601, and a motherboard 125. The liquid cooling system 1601 is like the liquid cooling system 101 (see FIG. 15), except that the liquid cooling system 1601 uses a TEG 1604 that is incorporated into the chip package 1501. In this example, the TEG 1604 is incorporated into the third chip 1503 just beneath the cold plate 115 and the cold plate 115 may be in direct contact with the third chip 1503. The TEG 1604 may be connected to the relay 109 by a wire 1605 that attaches to a contact pad 1607 on the third chip 1503.

FIG. 16B provides a cross-sectional view 1650 illustrating a portion of the third chip 1503 including the TEG 1604. As shown in FIG. 16B, the third chip 1503 includes the metal interconnect structure 1633 over the third semiconductor substrate 1505. Semiconductor devices such as a transistor 1643 may be formed on or in the third semiconductor substrate 1505. The metal interconnect structure 1633 comprises a plurality of metallization layers 1645, including an uppermost metallization layer 1645u, and a plurality of vias layers 1647. The metallization layers 1645 contain wires 1637 and the vias layers 1647 contain vias 1639. The TEG 1604 is disposed in a passivation stack 1646 over the uppermost metallization layer 1645u.

A first contact pad 1619 and a second contact pad 1621 may be disposed in a pad layer 1651 over the passivation stack 1646. A dielectric 1620 of the bonding layer 1623 surrounds and isolates the first contact pad 1619 and the second contact pad 1621. In some embodiments, the dielectric 1620 is a high thermal conductivity dielectric. In some embodiments, the dielectric 1620 is a very thermal conductivity dielectric. In some embodiments, the dielectric 1620 is an extremely high thermal conductivity dielectric. Having high thermal conductivity layers between the TEG 1604 and the cold plate 115 (see FIG. 16B) helps provide efficient cooling while sustaining a large temperature gradient across the TEG 1604.

The TEG 1604 comprises a first electrode 1648 and a second electrode 1630. A first via 1649 passes through the first electrode 1648 and the passivation stack 1646. The first via 1649 may couple the first electrode 1648 to either or both of the first contact pad 1619 and a first wire 1637A in the uppermost metallization layer 1645u. A second via 1627 passes through the passivation stack 1646 and the second electrode 1630. The second via 1627 may couple the second electrode 1630 to either or both of the second contact pad 1621 and a second wire 1637B in the uppermost metallization layer 1645u. In this way, the TEG 1604 may connect to the contact pad 1607 (see FIG. 16A) through either the pad layer 1651 or through the metal interconnect structure 1633. In some embodiments, the TEG 1604 is coupled to the transistor 1643 or some other structure that may be used to amplify a signal from the TEG 1604 before routing the signal to the relay 109 (see FIG. 16B).

The passivation stack 1646 is a dielectric structure that may include various layers, for example, an etch stop layer 1636, a dielectric layer 1631, and a barrier layer 1629. The etch stop layer 1636 may be a material such as silicon nitride (SiN), silicon carbide (SiC), silicon carbonitride (SiCN), silicon oxycarbide (SIOC), silicon oxycarbonitiride (SiOCN), a combination thereof, or the like. The dielectric layer 1631 may be a dielectric that provides electrical insulation between the N-type vias 305 and the P-type vias 307 of the TEG 1604 and between the third chip 1503 and an external environment. In some embodiments, the dielectric layer 1631 is silicon dioxide (SiO₂). In some embodiments, the dielectric layer 1631 is a low-k dielectric such as may be used as the interlevel dielectric 1638 in the metal interconnect structure 1633. A low-κ dielectric may be, for example, an organosilicate glasses (OSG) such as carbon-doped silicon dioxide, a fluorinated silica glass (FSG), a porous silicate glass, or the like.

In some embodiments, the barrier layer 1629 is a high thermal conductivity dielectric. In some embodiments, the barrier layer 1629 silicon nitride (Si₃N₄) or the like. Silicon nitride (Si₃N₄) provides superior moisture resistance and has greater mechanical strength than silicon dioxide (SiO₂). In some embodiments, the barrier layer 1629 is a very high thermal conductivity dielectric. In some embodiments, the barrier layer 1629 is an extremely high thermal conductivity dielectric.

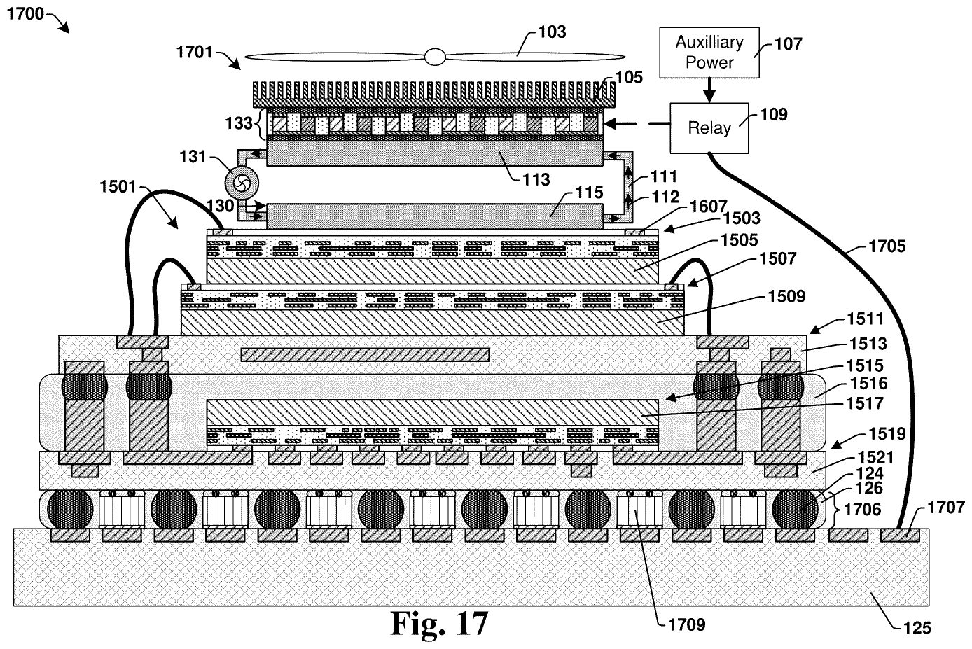

FIG. 17 illustrates a system 1700 in accordance with another embodiment. The system 1700 includes the chip package 1501, a liquid cooling system 1701, and the motherboard 125. The liquid cooling system 1701 is like the liquid cooling system 1601 (see FIG. 16A) except that instead of the TEG 1604 incorporated into the chip package 1501, the liquid cooling system 1701 uses one or more TEGs 1709 that are disposed between the chip package 1501 and the motherboard 125. The TEGs 1709 may be disposed in a connection layer 1706 between solder balls 124. A signal from the TEGs 1709 may be routed through the motherboard 125 and coupled to the relay 109 by a wire 1705 connected to a contact pad 1707 on the motherboard 125. The liquid cooling system 1701 may be used without altering the design of the chip package 1501 and without placing any heat-flow obstructing barrier between the chip package 1501 and the cold plate 115.

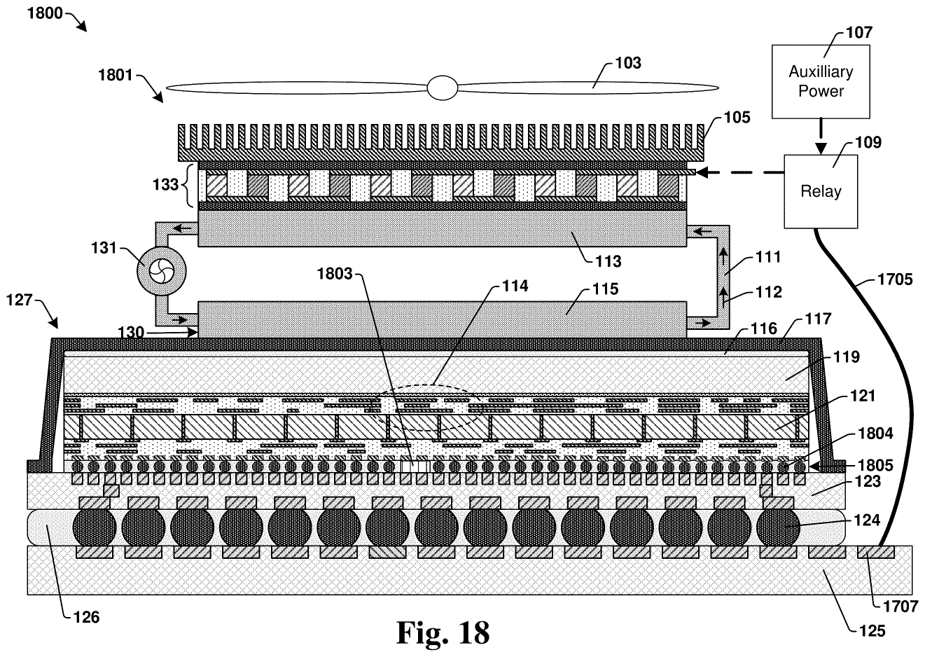

FIG. 18 illustrates a system 1800 in accordance with another embodiment. The system 1800 includes the chip package 127, a liquid cooling system 1801, and the motherboard 125. The liquid cooling system 1801 is like the liquid cooling system 101 (see FIG. 1) except that instead of the TEG 129, the liquid cooling system 1801 has a TEG 1803 that is incorporated into the chip package 127. The TEG 1803 may be between two device layers in the chip package 127 and in particular may be in a controlled collapse chip connection (C4) layer 1805 between solder bumps 1804. The TEG 1803 may be located near a hot spot 114, either between the hot spot 114 and the motherboard 125 or between the hot spot 114 and the cold plate 115. The cold plate 115 may be in abutment with the lid 117. A direct signal from the TEG 1803 or an amplified signal from the TEG 1803 may be routed through the chip package 127 to the motherboard 125 and from the motherboard 125 to the relay 109.

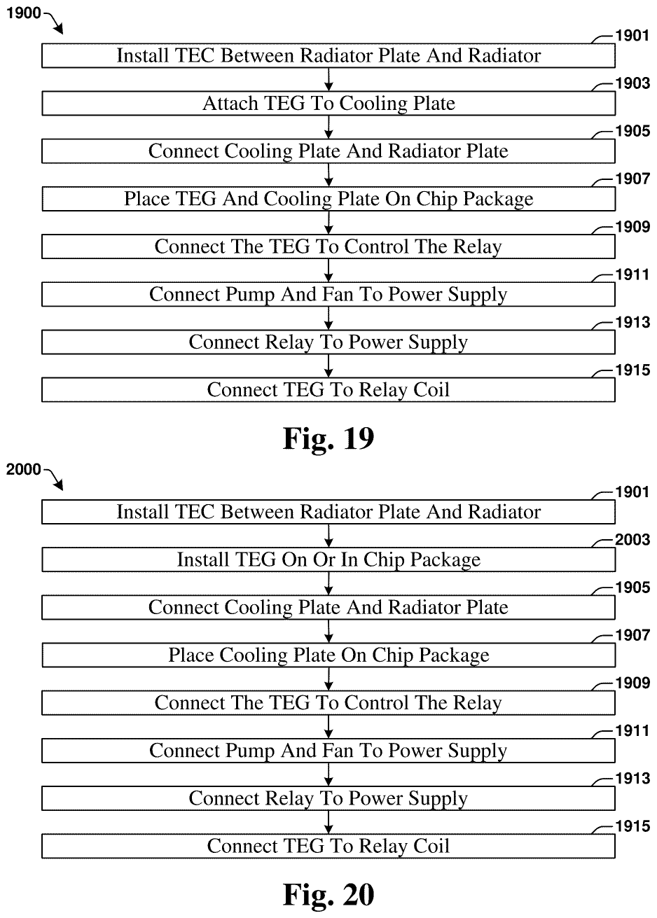

FIG. 19 provides a flow diagram for a method 1900 of forming a system that cools a chip package in accordance with some embodiments of the present disclosure. While the method 1900 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases. The system 100 of FIG. 1, the system 1100 of FIG. 11, the system 1500 of FIG. 15, or the like may be formed using the method 1900.

The method 1900 may begin with act 1901, installing a TEC between a radiator plate and a radiator. A thermal paste may be used to improve contact with the radiator plate and or the radiator. A fan may be positioned to move air over the radiator.

Act 1903 is attaching a TEG to a cold plate. Act 1905 is connecting the cold plate and the radiator plate by fluid carrying conduits such as tubes. Act 1907 is attaching the TEG and the cold plate to a chip package so that the TEG is between the cold plate and the chip package. A thermal paste may be used to improve contact between the TEG and the cold plate and or between the TEG and the chip package. In some embodiments, the TEG is clamped to the chip package. In some embodiments, the TEG is welded to the chip package.

Act 1909 is connecting the TEG so as to control a relay or some other switch through which the TEC is activated. In some embodiments, the TEG output is coupled directly to the coil of the relay. In some embodiments, the TEG is coupled to an amplifier and the amplified output of the TEG is sent to the relay.

Act 1911 is connecting a pump and a fan of the liquid cooling system to a power supply. Act 1913 is connecting the relay to a power supply. The relay may be connected to the same power supply as the pump and the fan or to a different power supply. Acts 1911 and act 1913 may be combined into a single act. Act 1915 is connecting the output of the relay to the TEC so that the TEC is controlled by the TEG through the relay.

FIG. 20 provides a flow diagram for a method 2000, which is a variation of the method 1900 and may be used to form the system 1400 of FIG. 14, the system 1600 of FIG. 16A, the system 1700 of FIG. 17, the system 1800 of FIG. 18, or the like. The method 2000 differs in two respects. One relates to installing the TEG, and the other relates to connecting the TEG to the relay.

Whereas the method 1900 includes act 1903, attaching the TEG to the cold plate, the method 2000 includes act 2003, installing the TEG on or in the chip package. The TEG may be installed on the chip package between a lid and the chip package as in the system 1400 of FIG. 14, somewhere inside the chip package as in the system 1600 of FIGS. 16A and 16B or the system 1800 of FIG. 18, within one of the chips in the chip package as in the system 1600 of FIGS. 16A and 16B, or on a side of the chip package opposite the cold plate as in the system 1700 of FIG. 17.

The method 2000 of FIG. 20 may also differ from the method 1900 of FIG. 19 in the method of executing act 1915, connecting the TEG to the relay. In the method 2000, the TEG may be connected to the relay through a contact pad on a lid as in the system 1400 of FIG. 14, through a contact pad on the chip package as in the system 1500 of FIG. 15 or the system 1600 of FIG. 16A, through the chip package as in the system 1600 of FIGS. 16A and 16B or the system 1800 of FIG. 18, or through a motherboard as in the system 1700 of FIG. 17 or the system 1800 of FIG. 18.

Some aspects of the present disclosure relate to a system that includes a chip package, a cooling system, a thermoelectric generator, and a relay. The cooling system includes a cold plate, a radiator plate, a fluid, and a pump configured to circulate the fluid between the cold plate and the radiator plate. The cold plate is positioned so as to cool the chip package. The thermoelectric generator has a hot side and a cold side and is positioned so that the hot side receives heat from the chip package. The relay is configured to be controlled by the thermoelectric generator so as to provide a selective connection between the cooling system and a power supply. In some embodiments, the cooling system further includes a thermoelectric cooler and a radiator. The first thermoelectric cooler is between the radiator plate and the radiator. The thermoelectric cooler is a part of the cooling system that is powered from the relay. In some embodiments, there is a second thermoelectric cooler and a second radiator. The second thermoelectric cooler is between the radiator plate and the second radiator. The first thermoelectric cooler and the second thermoelectric cooler are on opposite faces of the radiator plate. The second thermoelectric cooler is also powered from the relay.

In some embodiments, the thermoelectric cooler includes a plurality of thermoelectric modules on one face of the radiator plate. In some embodiments, the thermoelectric generator includes a plurality of thermoelectric modules connected in series to provide a switching voltage for the relay. In some embodiments, the thermoelectric generator is between the chip package and the cold plate. In some embodiments, in addition to the thermoelectric generator there is a thermally conductive block between the chip package and the cold plate. The thermally conductive block is lateral to the thermoelectric generator. In some embodiments, the thermally conductive block provides greater heat transfer between the chip package and the cold plate than does the thermoelectric generator.

In some embodiments, at least a part of the thermoelectric generator is within the chip package. In some embodiments, the chip package is operative to generate heat that raises an internal temperature of the chip package so as to produce a first temperature differential between the internal temperature and the hot side and a second temperature differential between the hot side and the cold side, and the first temperature differential is greater than the second temperature differential. In some embodiments, the chip package includes a plurality of device layers in a vertical stack.

Some aspects of the present disclosure relate to a system that includes a chip package, a cooling system, and a relay. The cooling system includes a thermoelectric cooler, a radiator, a cold plate, a radiator plate, a fluid, and a pump. The pump is configured to circulate the fluid between the cold plate and the radiator plate. The thermoelectric cooler is configured to move heat from the radiator plate to the radiator. The cold plate is positioned to cool the chip package. The relay provides power to the thermoelectric cooler and is switched on by heat from the chip package. In some embodiment, the system further includes a thermoelectric generator. The thermoelectric generator is configured to receive the heat from the chip package, generate an electrical current from the heat, and to switch on the relay with the electrical current. In some embodiments, the thermoelectric cooler includes two thermoelectric modules on opposite faces of the radiator plate. In some embodiments, the thermoelectric cooler includes a plurality of thermoelectric modules connected in series.

Some aspects of the present disclosure relate to a cooling system the includes a radiator plate, a cold plate, a pump configured to circulate fluid between the cold plate and the radiator plate, a radiator, a thermoelectric cooler configured to move heat from the radiator plate to the radiator, a thermoelectric generator attached to the cold plate, and a relay. The relay provides power to the thermoelectric cooler and is switched on by the thermoelectric generator. In some embodiments, a thermally conductive block is attached to the cold plate and is lateral to the thermoelectric generator. In some embodiments, the thermally conductive block has the same thickness as the thermoelectric generator. In some embodiments, the thermoelectric cooler includes two thermoelectric modules on opposite faces of the radiator plate. In some embodiments, the thermoelectric cooler includes a plurality of thermoelectric modules connected in series.

Some aspects of the present disclosure relate to a method of thermal management. The method includes providing a liquid cooling system, wherein the liquid cooling system includes a thermoelectric cooler, a radiator, a cold plate, a radiator plate, a fluid, and a pump. The pump is configured to circulate the fluid between the cold plate and the radiator plate. The thermoelectric cooler is between the radiator and the radiator plate. The method further includes placing the cold plate against a chip package, operating the chip package, and selectively operating the thermoelectric cooler according to a temperature differential, that is driven by heat from the chip package. In some embodiments, selectively operating the thermoelectric cooler according to the temperature differential includes using a thermoelectric generator to produce a current from the temperature differential and using the current to control a relay coupling the thermoelectric cooler to a power source.

In some embodiments, using the thermoelectric generator to produce a current from the temperature differential includes connecting a plurality of thermoelectric modules in series so that the thermoelectric generator closes the relay when a predetermined temperature differential is reached. In some embodiments, using the thermoelectric generator to produce a current from the temperature differential further includes connecting additional thermoelectric modules in parallel so that the thermoelectric generator provides enough current to switch the relay when the predetermined temperature differential is reached. In some embodiments, using the thermoelectric generator to produce a current from the temperature differential includes positioning the thermoelectric generator between the chip package and the cold plate. In some embodiments the method further includes providing a thermal coupling between a hot spot of the chip package and the cold plate, wherein the thermal coupling bypasses the thermoelectric generator.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A system, comprising:
a chip package;
a cooling system comprising a cold plate, a radiator plate, a fluid, and a pump configured to circulate the fluid between the cold plate and the radiator plate, wherein the cold plate is positioned to cool the chip package;
a thermoelectric generator having a hot side and a cold side, wherein the thermoelectric generator is positioned so that the hot side receives heat from the chip package; and
a relay configured to be controlled by the thermoelectric generator so as to provide a selective connection between the cooling system and a power supply.

2. The system of claim 1, wherein:
the cooling system further comprises a first thermoelectric cooler and a first radiator;
the first thermoelectric cooler is between the radiator plate and the first radiator; and
the first thermoelectric cooler is powered through the relay.

3. The system of claim 2, wherein:
the cooling system further comprises a second thermoelectric cooler and a second radiator;
the second thermoelectric cooler is between the radiator plate and the second radiator;
the first thermoelectric cooler and the second thermoelectric cooler are on opposite faces of the radiator plate; and
the second thermoelectric cooler is powered through the relay.

4. The system of claim 2, wherein the first thermoelectric cooler comprises a plurality of thermoelectric modules on one face of the radiator plate.

5. The system of claim 2, wherein the first thermoelectric cooler covers 70% or more of one face of the radiator plate.

6. The system of claim 1, wherein the thermoelectric generator comprises a plurality of thermoelectric modules connected in series to provide a switching voltage for the relay.

7. The system of claim 1, wherein the thermoelectric generator is between the chip package and the cold plate.

8. The system of claim 7, further comprising a thermally conductive block between the chip package and the cold plate and lateral to the thermoelectric generator, wherein the thermally conductive block provides greater heat transfer between the chip package and the cold plate than does the thermoelectric generator.

9. The system of claim 8, wherein the thermoelectric generator occupies 30% or less of an interfacial area between the chip package and the cold plate.

10. The system of claim 1, wherein at least a part of the thermoelectric generator is within the chip package.

11. The system of claim 1, wherein the chip package is operative to generate heat that raises an internal temperature of the chip package so as to produce a first temperature differential between the internal temperature and the hot side and a second temperature differential between the hot side and the cold side, wherein the first temperature differential is greater than the second temperature differential.

12. A cooling system, comprising:
a radiator plate;
a cold plate;
a pump configured to circulate fluid between the cold plate and the radiator plate;
a radiator;
a thermoelectric cooler configured to move heat from the radiator plate to the radiator;
a thermoelectric generator mounted to the cold plate; and
a relay, wherein the relay provides power to the thermoelectric cooler and is switched on by the thermoelectric generator.

13. The cooling system of claim 12, wherein the thermoelectric cooler comprises two thermoelectric modules on opposite faces of the radiator plate.

14. The cooling system of claim 12, wherein the thermoelectric cooler comprises a plurality of thermoelectric modules connected in series.

15. A method of thermal management, the method comprising:
providing a liquid cooling system that includes a thermoelectric cooler, a radiator, a cold plate, a radiator plate, a fluid, and a pump, wherein the pump is configured to circulate the fluid between the cold plate and the radiator plate, and the thermoelectric cooler is between the radiator and the radiator plate;
placing the cold plate against a chip package;
operating the chip package; and
selectively operating the thermoelectric cooler according to a temperature differential, wherein the temperature differential is driven by heat from the chip package.

16. The method of claim 15, wherein selectively operating the thermoelectric cooler according to the temperature differential comprises using a thermoelectric generator to produce a current from the temperature differential and using the current to control a relay coupling the thermoelectric cooler to a power source.

17. The method of claim 16, wherein using the thermoelectric generator to produce the current from the temperature differential comprises connecting a plurality of thermoelectric modules in series so that the thermoelectric generator closes the relay when a predetermined temperature differential is reached.

18. The method of claim 17, wherein using the thermoelectric generator to produce the current from the temperature differential further comprises connecting additional thermoelectric modules in parallel so that the thermoelectric generator provides enough current to switch the relay when the predetermined temperature differential is reached.

19. The method of claim 16, wherein using the thermoelectric generator to produce the current from the temperature differential comprises positioning the thermoelectric generator between the chip package and the cold plate.

20. The method of claim 19, further comprising providing thermal coupling between a hot spot of the chip package and the cold plate that bypasses the thermoelectric generator.
